(19) United States
(12) Patent Application Publication
(10) Pub. No.: US 2026/0090433 A1
(43) Pub. Date: Mar. 26, 2026

(54) 3D PRINTING OF GLASS CORE EDGE PROTECTION IN IC DEVICE PACKAGING

(71) Applicant: Intel Corporation, Santa Clara, CA (US)

(72) Inventors: Zhixin Xie, Chandler, AZ (US); Mohamed Saber, College Station, TX (US); Bohan Shan, Chandler, AZ (US); Anastasia Arrington, Queen Creek, AZ (US); Clay Arrington, Queen Creek, AZ (US); Jigneshkumar Patel, Chandler, AZ (US); Catherine Mau, Phoenix, AZ (US); Ryan Carrazzone, Chandler, AZ (US); Haobo Chen, Chandler, AZ (US); Wei Li, Chandler, AZ (US); Kyle Arrington, Gilbert, AZ (US); Ziyin Lin, Chandler, AZ (US); Dingying Xu, Chandler, AZ (US); Hongxia Feng, Chandler, AZ (US); Hiroki Tanaka, Gilbert, AZ (US); Brandon Marin, Gilbert, AZ (US); Jeremy Ecton, Gilbert, AZ (US); Benjamin Duong, Phoenix, AZ (US); Gang Duan, Chandler, AZ (US); Srinivas Pietambaram, Chandler, AZ (US); Praveen Sreeramagiri, Gilbert, AZ (US); Andrew Jimenez, Mesa, AZ (US); Yekan Wang, Chandler, AZ (US); Jung Kyu Han, Chandler, AZ (US)

(73) Assignee: Intel Corporation, Santa Clara, CA (US)

(21) Appl. No.: 18/898,414

(22) Filed: Sep. 26, 2024

(51) Int. Cl. H01L 23/498; H01L 23/14

(52) U.S. Cl. CPC H10W 70/69; H10W 70/695; H10W 90/401

(57) ABSTRACT

3D printing material in direct contact with edge of a glass core in IC packages to additively form a frame. Multiple such cores may be reconstituted into a panel that may then be built-up with routing metallization and assembled with IC die. Layers of printed material may be built up to form a frame with approximately the same thickness as the glass core and of any desired lateral width. The printed material may be an organic polymer or inorganic composition including metallics and ceramics. Beads of different material composition may be printed in succession to vary mechanical, electrical and/or thermal properties. A portion of the protective frame may be retained on an edge of the glass core when panels are singulated into package substrate units. Frame material may also be printed upon edges of glass-cored package units after their singulation.

### BACKGROUND

In integrated circuit (IC) device manufacturing, IC packaging comprises assembling an IC that has been monolithically fabricated on a chip (die or chiplet) comprising a semiconducting material into a “package” that can protect the IC chip from physical damage and support electrical contacts that connect the IC to a scaled host component. Multiple heterogenous chips can be similarly assembled, for example, into a multi-chip package (MCP).

A package substrate provides a means to connect chiplets and passives with extremely high I/O count to a host component, such as a printed circuit board (PCB). Package substrates are often built around a fiberglass resin core with copper on both sides, typically referred to as a copper clad laminate (CCL). The CCL facilitates the creation of redistribution metallization layers (RDL) that connect through the substrate core with plated through holes (PTH). The various RDLs are separated from each other by organic dielectric layers, known as build-up films, which are typically dry film laminates.

Package substrate processing has evolved beyond PCB processing through the use of specialized tooling, such laser drills, and lithography steppers that can reduce RDL feature dimensions to below 5 μm line/space (l/s). However, a transition from CCL cores to glass cores may be necessary to further scale feature sizes (e.g., to 2 μm l/s, and below) and/or to enable larger package substrate sizes (e.g., exceeding 120 mm×120 mm). The low fracture resistance (i.e., brittleness) of glass introduces new challenges during panel and/or unit handling throughout the course of a package substrate manufacturing process as well as during subsequent device transportation, installation, and end user operation.

For example, the singulation of device package panels can generate defects, such as cracks and chips, in an edge of the glass core. While such defects may not destroy the panel immediately, contact between the glass edge and a process tool and/or stress in the panel during thermal cycling as layers of different coefficient of thermal expansion (CTE) are stacked upon the core can cause cracks initiated at the edge to propagate through the core and damage a whole panel. One form of damage is core splitting where a glass core of some initial core thickness bifurcates along a plane parallel to the panel. Two sides of the panel may then peel away from each other.

Accordingly, edge protection techniques and materials that can mitigate mechanical failures of glass cores in IC device package substrates and/or provide a handling interface tools may engage with are commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A is a flow diagram illustrating methods of forming an IC die package substrate in which a frame material is 3D printed on a glass core edge of a panel, in accordance with some embodiments;

FIG. 1B is a flow diagram illustrating methods of forming an IC die package substrate in which a frame material is 3D printed on a glass core edge of a package unit, in accordance with some embodiments;

FIG. 1C is a flow diagram illustrating methods of forming an IC die package substrate in which a frame material is 3D printed on a glass core edge of a panel and a frame material is 3D printed on a glass cored edge of a package unit, in accordance with some embodiments;

FIGS. 2A and 2B are plan and cross-sectional views of a glass core, in accordance with some embodiments;

FIG. 3A is a plan view depicting application of frame material around a perimeter edge of a glass core with a planar 3D printing process, in accordance with some embodiments;

FIGS. 3B, 3C and 3D are cross-sectional views of 3D printed frame materials around a perimeter edge of a glass core, in accordance with some embodiments;

FIG. 4A is a plan view depicting application of frame material around a perimeter edge of a glass core with a vertical 3D print process, in accordance with some embodiments;

FIGS. 4B, 4C and 4D are cross-sectional views of 3D printed frame materials around a perimeter edge of a glass core, in accordance with some embodiments;

FIGS. 5A, 5B and 5C are isometric views of 3D printed frame materials on a perimeter edge of a glass core, in accordance with some embodiments;

FIG. 6 is a flow diagram of 3D edge frame printing methods, in accordance with some embodiments;

FIG. 7A is a plan view depicting planar 3D printing of frame material around perimeter edges of quarter panel glass cores reconstituted into a panel, in accordance with some embodiments;

FIG. 7B is a plan view depicting planar 3D printing of frame material between a frame preform and perimeter edges of quarter panel glass cores reconstituted into a hybrid panel, in accordance with some alternative embodiments;

FIG. 7C is a plan view depicting planar 3D printing of frame material around perimeter edges of glass core units reconstituted into a panel, in accordance with some embodiments;

FIG. 7D is a plan view depicting planar 3D printing of frame material between a frame preform and perimeter edges of glass core units reconstituted into a hybrid panel, in accordance with some alternative embodiments;

FIGS. 8A and 8B are plan and cross-sectional views illustrating a glass core with 3D printed frame material, in accordance with some embodiments;

FIGS. 9A and 9B are plan and cross-sectional views illustrating a package substrate build up upon a glass core with 3D printed frame material, in accordance with some embodiments;

FIG. 10 is a cross-sectional view illustrating singulation of package substrate units comprising a glass core, in accordance with some embodiments;

FIGS. 11A, 11B, 11C, and 11D are cross-sectional views illustrating a singulated package substrate unit comprising a glass core with 3D printed frame material, in accordance with some embodiments;

FIG. 12 is a cross-sectional view illustrating an electronic device comprising an IC die package including a glass core protected by 3D printed frame material, in accordance with some embodiments;

FIGS. 13A and 13B are plan and cross-sectional views illustrating IC die assembly and singulation of a panel of packaged IC devices comprising a glass core, in accordance with some embodiments;

FIG. 14 is a cross-sectional view illustrating a singulated package IC device comprising a glass core protected by 3D printed frame material, in accordance with some embodiments;

FIG. 15 is a cross-sectional view illustrating an electronic device comprising an IC die package including a glass core protected by one or more frame prints, in accordance with some embodiments;

FIG. 16 illustrates a mobile computing platform and a data server machine including an IC package comprising a glass core protected by 3D printed frame material, in accordance with some embodiments; and

FIG. 17 is a functional block diagram of an electronic computing device that may be included with a mobile or server computing platform, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

In accordance with embodiments herein, frame materials and structures are additively printed in direct contact with an edge of a glass core of an integrated circuit (IC) package substrate. In exemplary embodiments, one or more materials are 3D printed upon edges of a glass core preform to form a frame completely encircling the glass core. The frame may offer protection or stability to the glass core preform, and improve compatibility of the perform with certain manufacturing tools, as it is processed into a package substrate for an IC device. Multiple glass core preforms may be reconstituted into a panel that may then be built-up with routing metallization and assembled with IC die. The printed material may be layered to form a frame with approximately the same thickness as the glass core and of any desired lateral width. The printed material may be an organic and inorganic composition including metallics or dielectrics, or a composite of one or more organic compositions and one or more inorganic compositions. In some embodiments, material layers of different composition are printed in succession to form a layered frame with varying mechanical, electrical and/or thermal properties. In some embodiments, a frame print includes a shell, a portion of which is in direct contact with the edge of a glass core. The frame print further includes in-fill attached to the shell. The in-fill may have different porosity than the shell. A portion of a frame print may be retained on an edge of the core glass when panels are singulated into package substrate units. Beads or layers of material may also be printed upon edges of glass-cored package units after singulation, for example to protect and/or stabilize the glass core preform over its lifetime in the field.

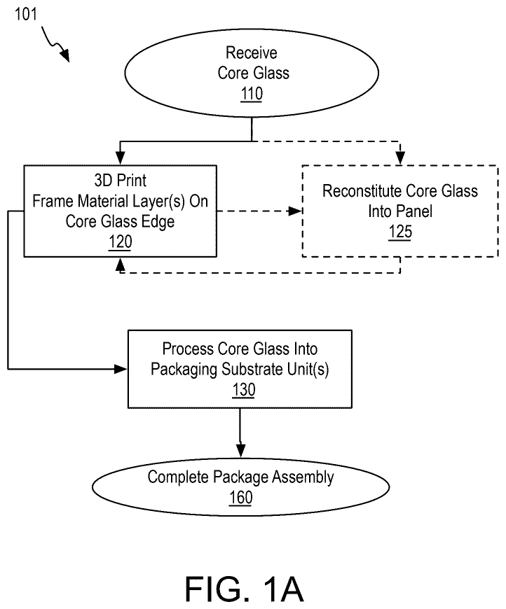

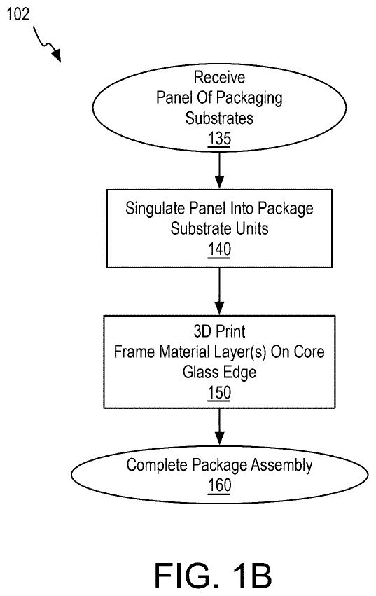

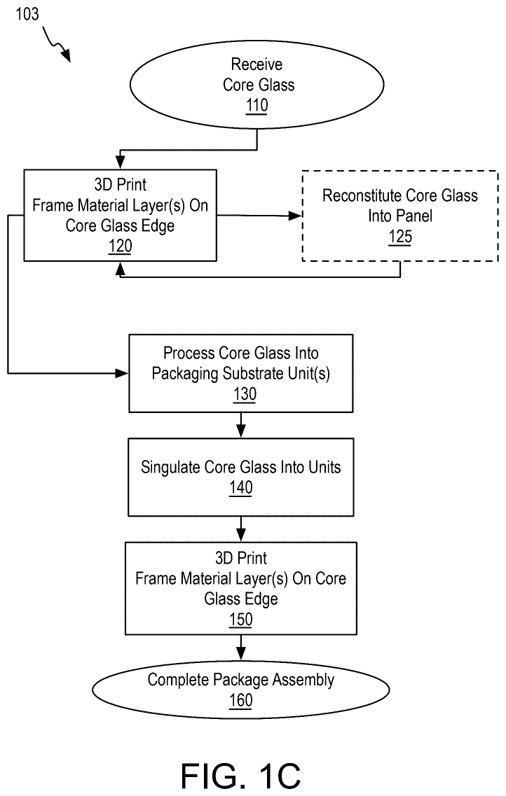

FIG. 1A is a flow diagram illustrating methods 101 for forming an IC die package substrate in which a frame material is 3D printed on an edge of a glass core, in accordance with some embodiments. Methods 101 begin where a core glass preform is received at input 110. The preform of core glass received may have any composition and form factor amenable to being further processed into a glass core of a package substrate.

Methods 101 continue at block 120 where a frame material is printed in direct contact with an edge of the core glass. Any 3D printing process may be practiced at block 120 to form a frame of material of suitable chemical, electrical, thermal and mechanical properties. In exemplary embodiments, the core glass is completely encircled by the printed frame material and may, for example, protect the glass core edge against scratches, chips, cracking, and other forms of mechanical damage. The printed frame material may also improve mechanical stability of core glass, functioning, for example, as a girdle, that may resist splitting of the core glass. The printed frame material may also provide an advantageous surface chemistry, such as greater hydrophobicity. Accordingly, the frame material printed at block 120 may have a wide range of chemical composition(s), and physical dimensions. Attributable to the printing method(s) practiced at block 120, the frame material has a layered and/or beaded macrostructure. As described further below, a printed layer and/or bead of frame material may be identified by the presence of a periodic surface feature, such as convex curvature, at one or more exterior surfaces of the frame material.

Depending on the physical dimensions of the core glass preform received at input 110, a plurality of the core glass preforms may be reconstituted into a larger panel at block 125. Reconstitution may be performed prior to printing frame material on edges of the core glass at block 120, or subsequent to printing frame material on the core glass edge(s) at block 120, or concurrently with the printing of frame material where the printed frame material physically joins adjacent ones of the glass preforms. For embodiments where a plurality of core glass preforms are reconstituted, reconstitution may be by any means, such as, but not limited to, thin film lamination over a front and/or back side of each of the preforms or an application and cure of a mold material. Edges of the preforms embedded within the reconstituted panel may comprise printed frame material for embodiments where frame material is printed on each preform prior to reconstitution. Alternatively, the reconstituted panel may comprise printed frame material only at an outer perimeter of the panel for embodiments where frame material is printed on exposed edges of the panel subsequent to reconstitution of the core glass preforms.

Methods 101 continue at block 130 where the core glass preform (or a panel of such preforms) is processed into one or more IC die packaging substrate units. Edges of the core glass preform(s) are protected during such processing by the frame material printed at block 120. While any substrate processing may be practiced at block 130, in some examples conductive through vias are formed through a thickness of the glass. For example, through via openings may be formed in the core glass at block 130 with a masked dry etch process or with a laser-assisted wet etch. One or more metals may then be deposited within the via openings, for example by electrolytic plating, physical vapor deposition, or chemical vapor deposition. Alternatively, conductive through vias may have been fabricated upstream of methods 101 such that the core glass preform received at input 110 includes the conductive through vias.

Block 130 may further entail the build-up of dielectric material and metallization levels on one or both sides of the core glass. Any number of package metallization levels and insulator levels (layers) may be built up over the glass core. Package build up may be according to any techniques known to be suitable for advanced package substrates. For example, dielectric material layers may be deposited (e.g., laminated) and patterned (e.g., lithographically), and electrically conductive materials may then be deposited upon the patterned dielectric surface to form a routing or redistribution metallization layers. Conductive material layers, for example comprising predominantly Cu, may be deposited by any known technique, such as plating. Following package build-up, methods 101 end at output 160 where package assembly is completed according to any known techniques.

FIG. 1B is a flow diagram illustrating methods 102 for forming an IC die package substrate in which a frame material is 3D printed on an edge of a glass core of a package unit, in accordance with some embodiments. In contrast to methods 101, methods 102 comprise 3D printing frame material on a core glass edge of individual IC die package substrate units following their fabrication. Such IC die package units may have been fabricated by methods 101, for example, or according to any known IC die package substrate fabrication technique(s) compatible with glass cores. As shown in FIG. 1B, methods 102 begin with receipt of a panel of packaging substrates at input 135. As received, the panel may comprise any number of routing metallization levels and dielectric material layers built up on front and/or back sides of the panel. At block 140, the panel is singulated according to any technique(s) compatible with glass cores, such as, but not limited to, mechanical sawing, laser ablation, or scribe-and-break. The panel may be singulated into any number of package substrate units, each having at least one exposed core glass edge.

Methods 102 continue at block 150 where frame material is printed upon exposed edges of the core glass. The frame material printed at block 150 may be any suitable material and any 3D printing technique suitable for the material may be practiced at block 150. With a protective frame print in direct contact with at least a portion of the glass core, methods 102 end at output 160 where package assembly is completed according to any known techniques.

FIG. 1C is a flow diagram illustrating methods 103 of forming an IC die package substrate in which a frame material is 3D printed on a core glass edge of a panel and a frame material is also 3D printed on a glass core edge of a singulated package unit, in accordance with some embodiments. Methods 103 may, for example, comprise the practice of methods 101 followed by the further practice of methods 102. In the practice of methods 103, edges of core glass preforms are first protected by 3D printing a frame material that at least encircles a panel of such preforms. The core glass panel is then processed into one or more packaging substrate units. Once singulated, the packaging substrate units are further processed to protect the glass core edge(s) by printing frame material that encircles each packaging substrate unit. The frame material printed at block 120 need not be the same as the frame material printed at block 150 and the printing techniques enlisted may also differ. With the package substrate unit protected by printed frame material, methods 102 end at output 160 where the package assembly is completed.

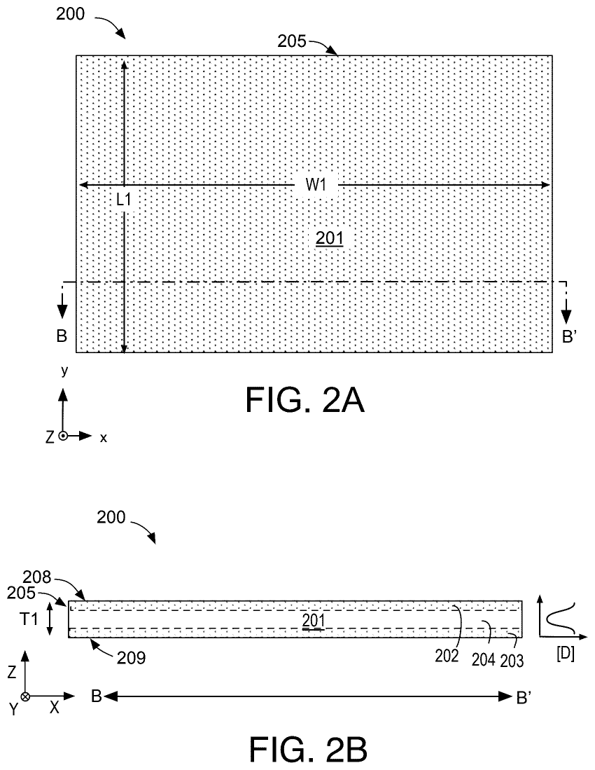

FIGS. 2A and 2B are plan and cross-sectional views of an exemplary core glass preform 200, in accordance with some embodiments. The core glass preform 200 advantageously comprises a single bulk piece of glass 201. Core glass preform 200 may comprise other components than core glass 201, such as a masking material, etc. In exemplary embodiments, core glass 201 is predominantly silica (e.g., silicon and oxygen) and may further include one or more compositional additives, such as, aluminum, beryllium, magnesium, calcium, strontium barium, radium, tin, sodium, silver potassium, boron, phosphorus, zirconium, lithium, titanium, or zinc. Core glass 201 may therefore be any of aluminosilicate, borosilicate, alumino-borosilicate, or silica, etc. The composition of core glass 201 may be primarily silicon, oxygen, and aluminum, for example. In some advantageous embodiments, core glass 201 has a composition of at least 23 weight percent silicon and at least 26 weight percent oxygen, and further comprising at least 5 weight percent aluminum.

The chemical composition of core glass 201 may be substantially homogeneous, or not. Core glass 201 may have nanosized aggregates of a different composition than a remainder of the bulk, for example. Core glass 201 may also have a varying compositional profile across thickness T₀. FIG. 2B, for example, illustrates two surface thicknesses or zones 202 and 203. Either (or both) of surface zones 202, 203 may have a different chemical composition than a remainder (e.g., center thickness or zone 204) of core glass 201. Surface zones 202, 203 may each have a thickness corresponding to 5-20% of thickness T₀, for example. As illustrated in the dopant concentration [D] profile of FIG. 2B, surface zone 202 and/or surface zone 203 has a higher concentration of one or more dopants D than the center zone 204 proximal to the half substrate thickness (T₁/2). Dopants D may, for example, increase the hardness of surface zones 202 and/or 203. Although the surface zone dopants may be any of those described above, in some exemplary embodiments surface zone 202 and/or 203 has more of K, Na, or Ag than center zone 204.

In exemplary embodiments, core glass 201 is substantially amorphous, but may alternatively have an ordered nanostructure or microstructure. Core glass 201 may be quartz glass, for example, having nanocrystalline, polycrystalline, or even substantially monocrystalline microstructure. Aggregates corresponding to compositional inhomogeneity may also have different microstructure than a remainder of core glass 201.

In the embodiment illustrated in FIG. 2A, core glass preform 200 is rectilinear (i.e., rectangular) having any x-axis and y-axis dimensions from 10-120 mm suitable for any of a single packaging unit (e.g., 10-120 mm), a fractional panel (e.g., ¼ panel), or a whole panel (e.g., 510 mm×515 mm and 600 mm×600 mm) that is to be further processed into any number of IC die packaging substrates. FIG. 2B illustrates a cross-section through core glass 201 along the B-B′ line shown in FIG. 2A. Core glass 201 has a thickness T₁ between a first (e.g., bottom) glass surface 208 and a second (e.g., top) glass surface 209. In exemplary embodiments, thickness T₁ is less than 2 mm, advantageously less than 1 mm, and more advantageously no more than 500 μm (e.g., 200-400 μm).

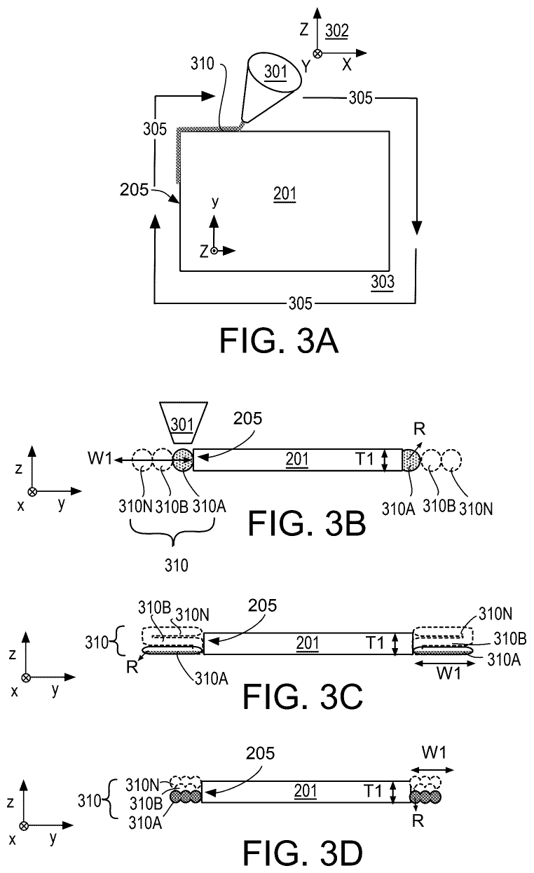

FIG. 3A is a plan view depicting the printing of a frame material 310 around a perimeter edge 205 of core glass 201 positioned so that edge 205 is substantially orthogonal to a print bed surface 303, in accordance with some embodiments. As shown, a front or back side surface of core glass 201 defines a workpiece x-y plane when positioned on print bed 303. The stage may be physically displaceable along any of the workpiece x-y-z axes. 3D print head 301 may be similarly displaceable along any dimension of a print head axis 302 to follow a preprogrammed print path 305 relative to core glass 201. While traversing print path 305, one or more beads or layers of frame material 310 are output by print head 301. At least one layer of frame material 310 is printed adjacent to, and in direct contact with, glass edge 205. In exemplary embodiments, a plurality of layers of frame material 310 are printed in succession to build-up frame material 310 to a predetermined frame thickness (e.g., z-dimension) and/or lateral frame width (e.g., x-y dimensions).

FIG. 3B-3D are cross-sectional views further illustrating frame material 310 encircling perimeter edge 205, accordance with some embodiments. In FIG. 3B, frame material 310 comprises a first printed layer or bead 310A in direct contact with glass edge 205. Depending on the printed layer height and/or bead cross-section, one or more beads or layers may be stacked one upon the other so that frame material 310 has a thickness of at least glass thickness T₁. In embodiments herein, layer height may vary with implementation, but in some examples ranges from less than a micrometer (e.g., 0.5 μm) to a 100 μm, or more. In the example illustrated in FIG. 3B, layer height (or bead diameter) is approximately equal to glass thickness T₁ so that only a single layer/bead 310A is in direct contact with glass edge 205.

Surface features associated with layer/bead 310A may comprise surface curvature, for example resulting from viscous flow. The surface curvature is convex with a radius of curvature R, which may vary with a layer height/bead diameter defined by the printing process. In some embodiments surface curvature radius R is no greater than the thickness of the glass core, advantageously no more than one-half the thickness of the glass core, and more advantageously less than one-fourth of the thickness of the glass core. Notably, the illustrated convex surface curvature is a structural feature indicative of a variety of 3D printing techniques, for example associated with a viscous fluid flow of an extruded melt, viscous flow of a fluid precursor prior to chemical curing, or viscous flow of a thermally fused powder. In contrast, other techniques more typically employed in the fabrication of IC packaging substrates, such a dry film lamination, molding, roll coating, or thin film deposition, etc., will not generally form periodic feature surfaces, such as convex curvature, at one or more exterior surfaces of the material.

As further illustrated in FIG. 3B, any number of additional material beads or layer (e.g., 310B, 310N) may extend outwardly from glass edge 205 to reach a lateral frame width W1 of that is sufficiently large to provide adequate protection and/or stabilization of core glass 201. Lateral width W₁ may vary with implementation, but in some examples ranges from less than a micrometer (e.g., 0.5 μm) to a 100 μm, or more. Surface features, such as convex curvature, indicative of the printing technique may be present on one or more surfaces of each material layer, the layer surface feature(s) being replicated with each printing pass. Accordingly, for multi-layered frame material embodiments, surface feature(s) may be periodic over the thickness (z-axis) and/or the lateral width (x, y axes) of frame material 310.

FIG. 3C further illustrates an embodiment where a material layer 310A is substantially planar with a first (e.g., back) side of core glass 201. Depending on the layer height, one or more additional layers 310B, 310N may be printed so that frame material 310 comprises a stack of a plurality of printed material layers adjacent to glass edge 205. For such embodiments, a portion of each frame material layer 310A-310N is in direct contact with glass edge 205. As shown, a sufficient number of layers of a predetermined layer height may be printed such that frame material 310 has a cumulative thickness (e.g., along z-axis) of at least glass thickness T₁. In the frame printing orientation illustrated in FIG. 3C, a frame of any lateral width W₁ may be defined within each material layer 310A-310N and convex surface curvature with one or more radii R may only be evident at an exterior edge of each layer of frame material 310 that is opposite glass edge 205.

FIG. 3D further illustrates embodiments where frame material 310 is printed with smaller layer height and/or bead cross-sectional area than in the example of FIG. 3C. As shown in FIG. 3D, each printed layer 310A, 310B, 310N is substantially coplanar with the workpiece plane and comprises a plurality of print lines or beads defining frame width W₁ from glass edge 205. Exterior surfaces of each print line or bead has convex curvature of radius R, which in this example, is significantly smaller than core glass thickness T₁.

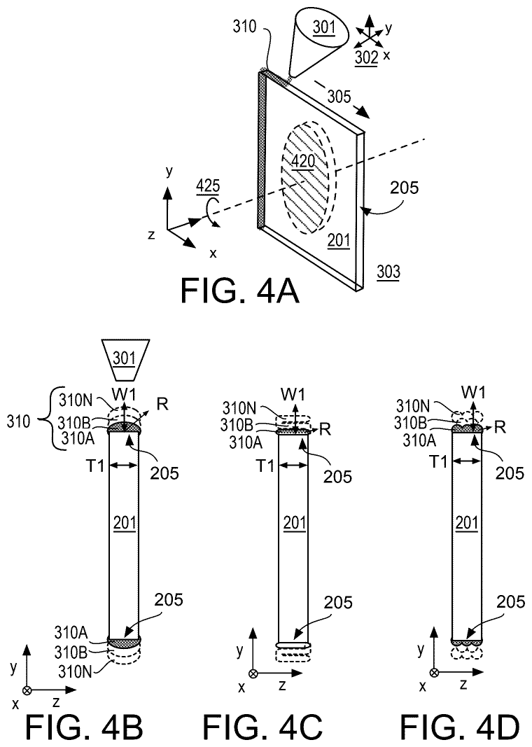

FIG. 4A is a plan view illustrating the printing of frame material 310 around a perimeter of glass edge 205, in accordance with some alternative embodiments. In this example, core glass 201 is held so that edge surface 205 is substantially parallel with print bed surface 303. In the illustrated example, vertical chuck surfaces 420 are affixed to at least one of a front side surface or back side surface of core glass 201. With core glass 201 held in the illustrated orientation, for example with vacuum force, core glass 201 may be physically displaceable along any of the workpiece x-y-z axes. 3D print head 301 may be similarly displaceable along any dimension of a printhead axis 302 to follow a preprogrammed print path 305 relative to core glass 201. In some embodiments, chuck 420 may rotate core glass 201 about a workpiece axis (e.g., z-axis) that is substantially parallel to glass edge 205. Glass or print head translation and/or glass rotation 425 may occur while one or more beads or layers of frame material 310 are output by print head 301. At least one layer or bead of frame material 310 is printed directly on glass edge 205. In exemplary embodiments, a plurality of layers of frame material 310 are printed in succession to build-up frame material 310 to a predetermined lateral frame width (e.g., y-x dimensions of core glass 201) and/or frame thickness (e.g., z dimension of core glass 201).

FIGS. 4B, 4C and 4D are cross-sectional views of 3D printed frame materials around a perimeter edge of a glass core, in accordance with some embodiments. In FIG. 4B, frame material 310 comprises a first printed layer or bead 310A in direct contact with glass edge 205. Depending on the printed layer height and/or bead cross-section, one or more beads may be layered or stacked one upon the other so that frame material 310 has a lateral width of W₁. Lateral width W₁ may vary with some examples ranging from less than a micrometer (e.g., 0.5 μm) to a 100 μm, or more. In the example illustrated in FIG. 4B, layer width (or cumulative bead diameter) is approximately equal to glass thickness T₁ so that only a single layer/bead 310A is in direct contact with glass edge 205.

Convex surface curvature associated with layer/bead 310A has a radius of curvature R, which may again vary with a layer height/bead diameter defined by the printing process as wells as properties of the print material. In some embodiments surface curvature radius R is no greater than the thickness of the glass core and advantageously no more than one-half the thickness of the glass core, and more advantageously less than one-fourth of the thickness of the glass core. For embodiments with multiple material layers or beads (e.g., 310B, 310N) extending outwardly from glass edge 205 to provide adequate stabilization of core glass 201, surface features indicative of the printing technique may be present on one or more surfaces of each material layer.

FIG. 4C further illustrates an embodiment where frame material layer 310A is substantially orthogonal to a first (e.g., back) side of core glass 201. Depending on the layer height, one or more additional layers 310B, 310N may be printed so that frame material 310 comprises a stack of a plurality of printed material layers adjacent to glass edge 205. For such embodiments, only frame material layer 310A is in direct contact with glass edge 205 with other layers being separated from edge 205 by underlying frame material layers. In the frame printing orientation illustrated in FIG. 3C, a frame of any thickness may be defined with each material layer 310A-310N and convex surface curvature with one or more smaller radii R may only be evident at an exterior edge of each layer of frame material 310, coplanar with a first (e.g., front) or second (e.g., back) side of core glass 201.

FIG. 4D further illustrates embodiments where frame material 310 is printed with smaller layer height and/or bead cross-sectional area than that illustrated in FIG. 4A. As shown in FIG. 4D, each printed layer 310A, 310B, 310N is substantially orthogonal to the workpiece x-y plane and comprises a plurality of print layers or beads defining a frame thickness of at least glass thickness T₁ to completely cover glass edge 205. Exterior surfaces of each print layer or bead may have convex curvature of radius R, which in this example is significantly smaller than core glass thickness T₁.

In accordance with some embodiments, a core glass frame comprises a shell and an infill. A sidewall of the frame shell is in direct contact with the core glass, and more particularly in direct contact with an edge of the core glass. The shell may further comprise one or more exterior surfaces of the frame with the infill occupying some fraction of the internal volume defined by the frame shell. At least one of material layer orientation, material (chemical) composition, or material porosity may vary between the frame shell and the frame infill.

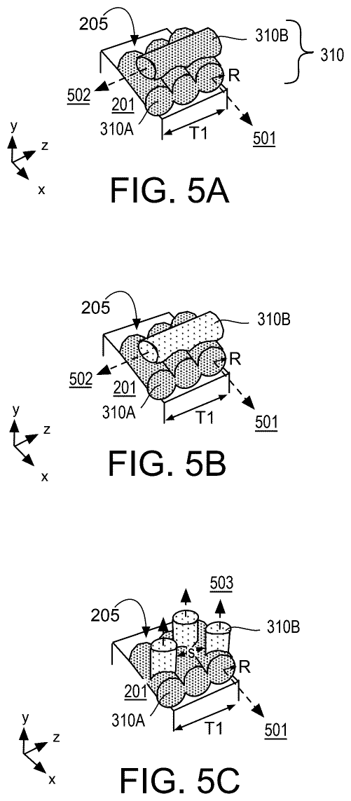

FIG. 5A-5C depict isometric views of 3D frame prints on a perimeter edge of core glass 201, in accordance with some embodiments. In FIG. 5A, a shell of frame material 310 comprises frame material layer 310A in direct contact with core glass edge 205. In this example, frame material layer 310A comprises a plurality of printed beads or lines having a longitudinal axis 501 extending in a first direction (e.g., along x-axis) parallel to edge 205. Frame material layer 310B is an infill layer and, in this example, frame material layer 310B comprises a plurality of beads or lines having a longitudinal axis 502 extending in a second direction (e.g., along x-axis) parallel to edge 205. In this example, both material layers 310A and 310B have the same chemical composition.

Frame material layers 310A and 310B may be an inorganic or organic material, or a composite thereof. In some inorganic embodiments, frame material layers 310A and 310B are either metallic or a ceramic. Exemplary metallics include alloys of titanium, (stainless) steel, copper, titanium, tungsten, aluminum, chrome, cobalt, or nickel. Exemplary ceramics include alumina, aluminum nitride, zirconia, silicon carbide and silicon nitride. Organic embodiments may include a polymeric material. Exemplary polymeric materials include acrylonitrile butadiene styrene (ABS), polycarbonate (PC), thermoplastic elastomers (TPE) such as polyethylene terephthalate (PET), polylactic acid (PLA), nylon, thermoplastic polyurethane (TPU), poly ether ester ketone (PEEK), polyetherimide (ULTEM), polyamides, silicones, and epoxies (e.g., an acrylate of novolac such as epoxy phenol novolacs (EPN) or epoxy cresol novolacs (ECN), aliphatic epoxy. In other embodiments, frame material layers are a composite material. Composite materials include one or more organic or inorganic fillers in a resin matrix. Fillers may be fibrous, for example including chopped or continuous carbon fiber, Kevlar fiber, or glass fiber. Fillers may also be non-fibrous, for example including diatomaceous earth or minerals such as perlite. Resins may generally be organic, for example including epoxies (e.g., any of those listed above).

In some embodiments, one or more frame material layer is hydrophobic. On a glass edge, the chemical structure of silicon dioxide may change when exposed to moisture (atmospheric water) to reveal surface hydroxyl groups at the edge of each unit. The inventors have noted that once a microfracture or imperfection forms at this edge surface, additional hydroxyl groups can form in response to Si—O—Si bond failures. Hydrogen bonding stemming from interaction between atmospheric water molecules and the newly revealed OH on the surface of the glass can therefore induce stress at the interface and propagate a crack or other defect deeper into the substrate. However, a hydrophobic frame material, particularly when in direct contact with a glass edge may hinder the hydroxyl group interaction and defect propagation. Accordingly, in some advantageous embodiments, a frame material layer in direct contact with a core glass edge has a chemical composition with at least ten atomic percent (at. %) carbon or at least ten at. % fluorine. In some examples, the frame material layer comprises a polyolefin (e.g., polypropylene), a fluorinated polymer (e.g., PTFE, PFPE, PFDA) or a fluorinated silicon.

At least a portion of a frame print shell in direct contact with the core glass edge may have a larger elastic modulus than an infill of a frame print. Additionally, or in the alternative, at least a portion of the shell defining an exterior surface of the frame may have a smaller elastic modulus of the infill. FIG. 5B illustrates through the use of different field lines an embodiment where frame material layer 310A (e.g., a shell layer) has a first composition, and frame material layer 310B (e.g., an infill layer) has a second composition. The first composition may be a first of any of the above exemplary compositions while the second composition may be a second of any of the above exemplary compositions, for example. In the illustrated embodiment, print orientation also varies between frame material layer 310A and frame material layer 310B. However, print orientations need not vary between layers of different composition.

In some embodiments, frame material layer 310A is of a material having a larger (higher) elastic modulus than that of frame material layer 310B. The larger modulus of frame material layer 310A may mechanically stabilize core glass 201, for example as a girdle or belt encircling a perimeter of core glass 201. A smaller modulus of frame material layer 310B may better dissipate or absorb external forces, preventing them from being applied to glass edge 205. In alternative embodiments, frame material layer 310A is of a material having a smaller (lower) elastic modulus than that of frame material layer 310B. A smaller modulus of frame material layer 310A may better dissipate or redirect external forces away from glass edge 205 while a larger modulus of frame material layer 310B may better sprend external forces over a larger area of a frame print, improving resilience.

In other examples, at least a portion of a frame shell in direct contact with the core glass edge may have a lower porosity than an infill of the frame. Additionally, or in the alternative, at least a portion of the shell defining an exterior surface of the frame has a lower porosity of the infill. Porosity variation may be employed to modulate one or more of average stiffness or average hardness of infill and shell portions of a frame. Porosity variation may be associated with intrinsic porosity differences of different material compositions utilized in different portions of a frame, or porosity variation may be associated with different printing paths utilized in different portions of a frame. FIG. 5C illustrates an exemplary embodiment where frame material layer 310B comprises nubs or pillars of print material having a longitudinal axis orientation 503, which are spaced apart by an interstitial space S that increases average porosity of material layer 310B beyond the intrinsic porosity of the particular material composition printed. Space S may vary with implementation, for example from submicron to 5-10 μm, or more. Such print porosity control may enable infill and shell portions of a frame to have dramatically different mechanical, electrical, and/or thermal properties that can be tuned to protect and/or stabilize core glass 201. In the embodiment illustrated in FIG. 5C, print orientation and material composition also varies between frame material layer 310A and frame material layer 310B. However, print orientations and material composition need not vary between layers of different porosity.

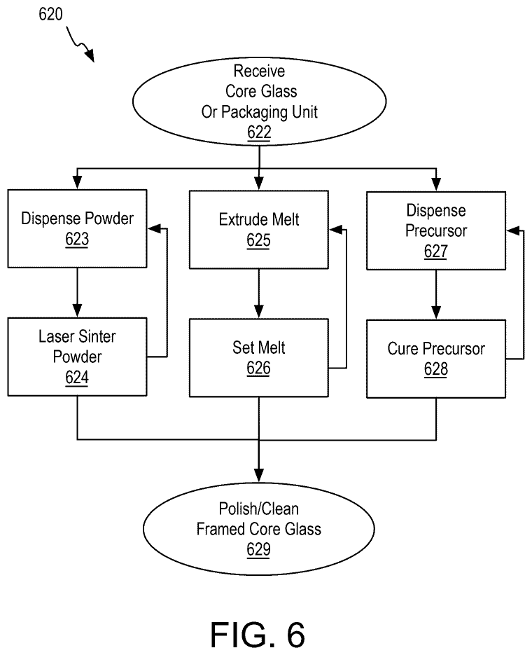

As noted above, a frame material in accordance with embodiments herein may be printed through a variety of techniques. FIG. 6 is a flow diagram of 3D edge frame printing methods 620, in accordance with some exemplary embodiments including selective laser sintering (SLS), fused deposition modeling (FDM), stereolithography (SLA) or direct ink write. Methods 620 begin with receipt of a core glass preform or a singulated packaging unit comprising a glass core at input 622. For SLS embodiments, methods 620 continue at block 623 where a powder is dispensed over a powder bed and in contact with a core glass edge. The SLS technique may implement either of the exemplary printing processes illustrated in FIG. 3A or FIG. 4A where print head 301 represents laser control, for example by a galvanometer. The dispense at block 623 may be with squeegee or a variable doser, for example. At block 624, laser irradiation of the powder selectively fuses the powder into a solid material layer on the glass edge. Blocks 623 and 624 may be iterated, for example with the glass core rotated to present a new edge, to form one or more frame material layers encircling the core glass edge.

In FDM embodiments, methods 620 continue at block 625 where a melt is extruded in contact with a core glass edge. The FDM technique may implement either of the exemplary printing processes illustrated in FIG. 3A or FIG. 4A where print head 301 represents a thermal extruder. At block 626, the melt fuses and sets into a solid upon cooling. Blocks 625 and 626 may be iterated, for example with the glass core rotated to present a new edge, to form one or more frame material layers encircling the core glass edge.

In SLA embodiments, methods 620 continue at block 627 where a chemical precursor is dispensed. In exemplary embodiment the chemical precursor is a viscous photopolymer resin that is dispensed and then cured at block 628, for example through exposure to UV light controlled by a digital light projector or a laser galvanometer. Blocks 627 and 627 may be iterated, for example with the glass core rotated to present a new edge, to form one or more frame material layers encircling the core glass edge.

After printing the frame material layers, methods 620 continue at output 629 where the printed frame material may be planarized with a front side and/or back side surface of the core glass, for example through a polishing process. Any planarization process suitable for planarizing packaging substrates may be practiced at output 629 in preparation for subsequent substrate processing, such as through via fabrication and/or build-up of electrical routing metallization.

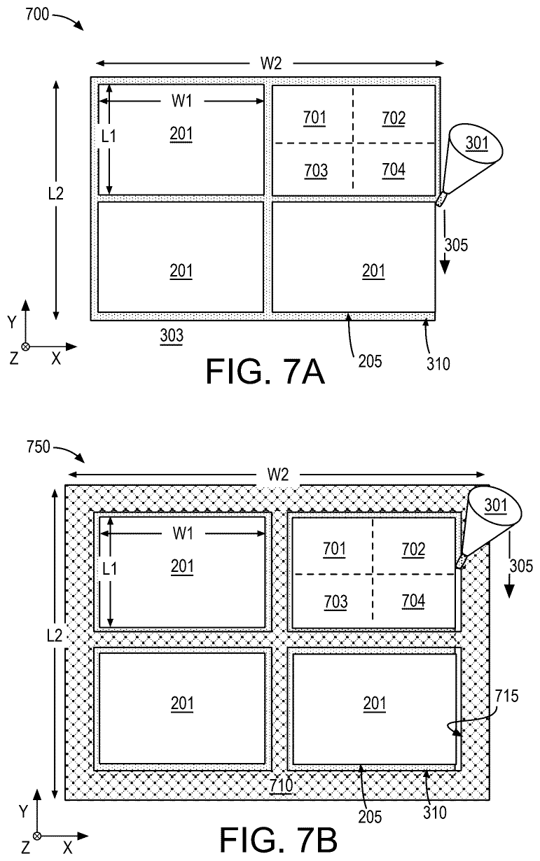

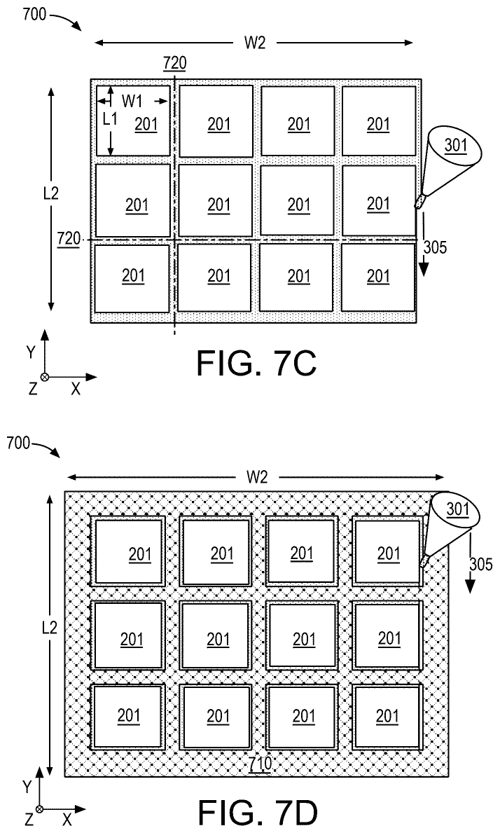

As noted above, frame material may be printed before, after, or concurrently with the reconstitution of multiple core glass preforms into a larger panel for package substrate processing. The glass preforms may be dimensioned to any fraction of a panel, from half-panel preforms to single packaging unit preforms. FIG. 7A is a plan view depicting the printing of frame material 310 around perimeter edge 205 of four quarter panels of core glass 201 reconstituted into a panel 700. Each quarter panel core glass 201 has a length L1 and width W1. Printed frame material 310 may be the only material joining the quarter panel core glass into a panel, at least before any additional material such as a dry film is laminated over a front side or back side of panel 700. As shown, the core glass 201 quarter panels are placed in a 2D array over print bed 303. Print head 301, following path 305 prints frame material 310 to define a panel of a larger length L2 and width W2. For some embodiments where L2 and W2 are each 500-550 mm, core glass quarter panel length L1 and width W1 may each be 100-120 mm, for example. Following the frame printing process, frame material 310 is both encircling a perimeter edge of panel 700 and encircling each quarter panel. Package substrates may then be fabricated from panel 700 and each quarter panel 201 may be subsequently singulated into one or more smaller IC die packaging substrate units 701, 702, 703, 704.

A panel comprising both core glass and a frame print may further include other preforms, such as a frame preform. For such embodiments, frame printing may be utilized to join a core glass preform with a non-glass frame preform into a hybrid panel. FIG. 7B is a plan view depicting a printing of frame material 310 between a frame preform 710 and perimeter edge 205 of four quarter panel glass cores 201 reconstituted into a hybrid panel 750, in accordance with some embodiments.

Frame preform 710 may comprise one or more materials and have any dimensions compatible with that of core glass preforms. In the illustrated example, frame preform 710 is a unitary body comprising one or more contiguous material layers. In some exemplary embodiments, frame preform 710 is a laminate of metallization and dielectric material, and may be any known CCL, for example. Frame preform 710 may include a rigid core, such as an epoxy-based laminate (e.g., FR4), or silicon (e.g., monocrystalline) for example. Alternatively, frame preform 710 or may be coreless. Frame preform 710 defines an exterior hybrid panel length L2 and width W2, which are larger than a glass core panel length L1 and width W1, respectively, by an amount sufficient to accommodate a space between an interior frame edge 715 and glass panel edge 205. As illustrated, frame material 310 is printed within this space, for example filling a 1-3 cm while gap. Frame material 310 therefore encircles each quarter panel of core glass 201.

FIG. 7C further illustrates a panel 700 implemented with a greater number of glass preforms. In this example, each preform of core glass 201 is dimensioned for a single packaging substrate unit. Frame material 310 is printed around the edge of each preform of core glass 201 and between edges of adjacent core glass preforms. Frame material 310 may be the only material joining the preforms of core glass 201. Following fabrication of packaging material layers on one or both sides of panel 700, singulation of packaging units may be along kerf lines 720 passing through frame material 310 such that no core glass is cut or exposed during singulation. This panel architecture may reduce demands on package substrate singulation and/or limit glass edge exposure to the panel assembly, which is an early phase of package substrate manufacturing.

FIG. 7D further illustrates hybrid panel 750 implemented with a greater number of glass preforms. In this example, singulation kerf lines 720 may again be excluded from core glass 201 and each packaging substrate unit may retain at least frame material 310 around the core glass edges and may further retain a portion of frame preform 710.

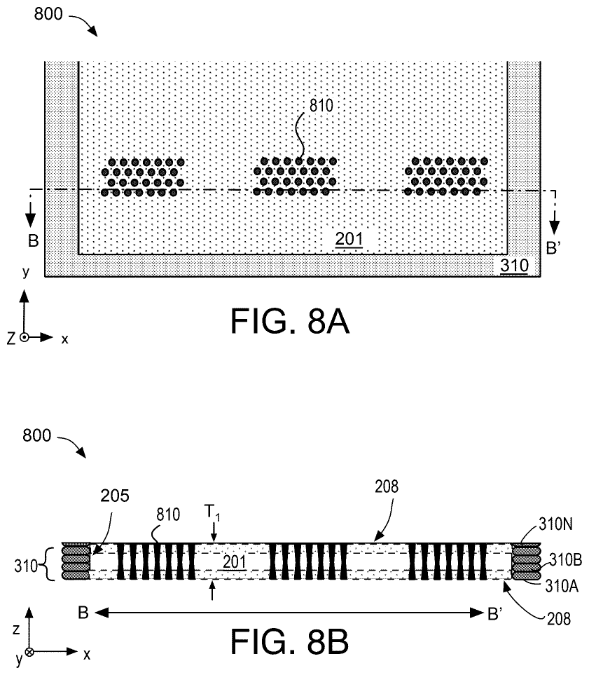

FIGS. 8A and 8B are plan and cross-sectional views illustrating a package substrate 800 comprising a glass core with 3D printed frame material, in accordance with some embodiments where metallization features are formed within regions of core glass 201. In the illustrated example, the metallization features comprise conductive through vias 810, which extend completely through core glass thickness T₁ and may therefore referred to as through-glass vias (TGVs). In the illustrated examples, conductive through vias 810, intersect both opposing glass surfaces 208, 209 and have an hour-glass profile, which is indicative of a double-sided via etch process. Conductive through vias 810 may be arrayed over an area, or footprint of core glass 201. Each conductive through via 810 comprises a conductive material, such as a metal, embedded within glass 201. In some examples, the metal is predominantly copper (Cu). Conductive through vias 810 may have any pitch in the x and/or y dimensions.

FIG. 8B further illustrates a planarization of frame material 310 where frame material layer 310N has been thinned by a planarization process (e.g., polish) to be coplanar with glass surface 208. A difference in thickness between frame material layer 310N and frame material layer 310B is indicative of a front-side planarization process. Since frame material layer 310A has substantially the same thickness as frame material layer 310B, no back-side planarization has been performed subsequent to printing frame material layer 310A.

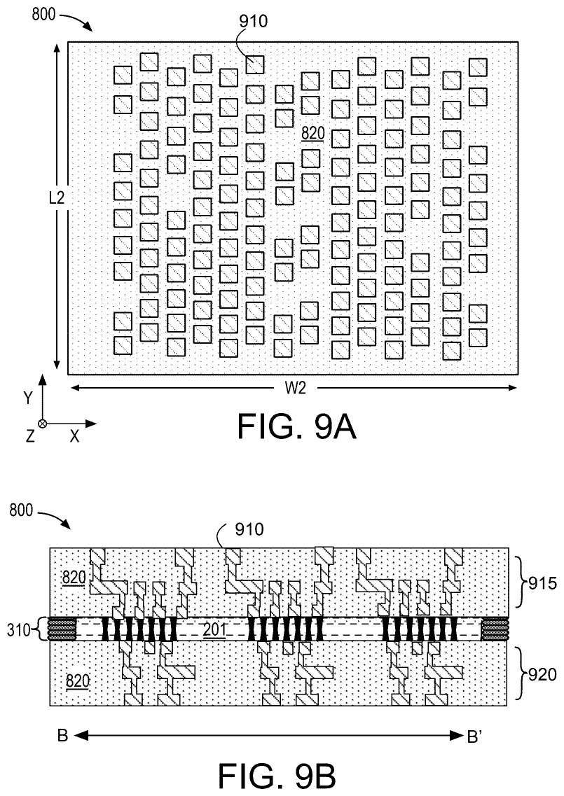

FIGS. 9A and 9B are plan and cross-sectional views illustrating a buildup on package substrate 800, in accordance with some embodiments. Package interconnect metallization levels may be built up on one or more sides of core glass 201. FIGS. 9A and 9B illustrate a front side redistribution layer (RDL) structure 915, in accordance with some embodiments. FIG. 9B further illustrates a back side RDL structure 920. Each of RDL structures 915 and 920 includes a plurality of levels of metallization features 910 embedded within one or more organic dielectric materials 820. As further shown in FIG. 9B, printed frame material 310 is embedded between RDL structures 915 and 920, remaining in direct contact with an edge of core glass 201. Dielectric material 820, in direct contact with frame material 310 may leave an exterior edge of frame material 310 exposed (as illustrated) or may instead fully encapsulate frame material 310. In some embodiments, dielectric material 820 is a dry dielectric film laminated over both frame material 310 and core glass 201. In other embodiments, a flowable epoxy is applied over both frame material 310 and core glass 201, and subsequently cured according to any suitable molding processing. Dielectric material 820 may be an organic dielectric, such as, an epoxy resin, phenolic-glass, or a resinous film such as the GX-series films commercially available from Ajinomoto Fine-Techno Co., Inc. (ABF), for example. RDL structures 915 and 920 each include a plurality of levels of metallization features 910 embedded within dielectric material 820. In exemplary embodiments, metallization features 910 are predominantly Cu.

Although not illustrated, one or more devices may be embedded within package build up or core glass 201. For example, an interconnect bridge die may be embedded within package dielectric material 820. An interconnect bridge die may have interconnect routing features fabricated at monolithic chip-scale, which may be of significantly higher density than the routing of RDL structures 915, 920.

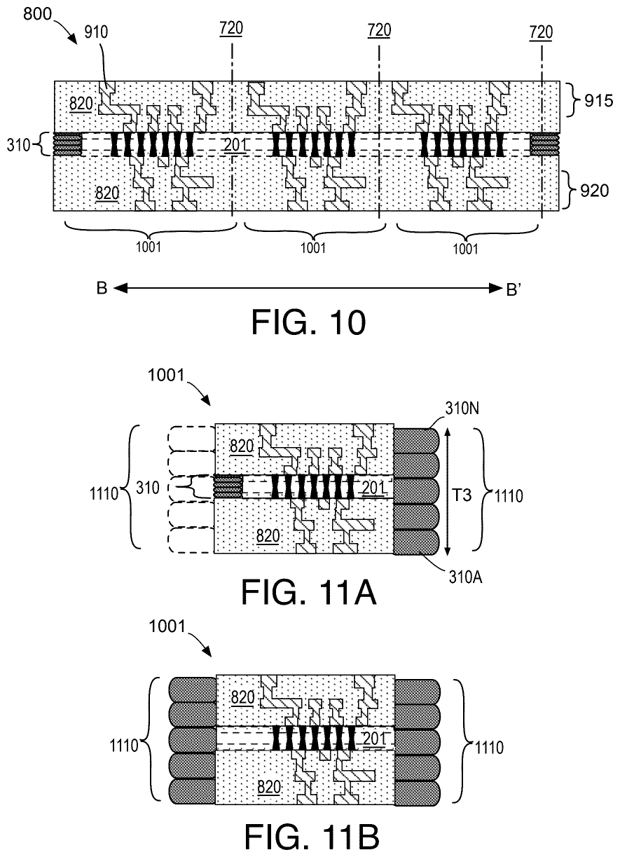

Following fabrication of a package substrate including a glass core and printed frame, the package substrate may be singulated into units before or after assembly with one or more IC die. As described above (e.g., in the context of FIGS. 1B and 1C), frame material may be printed upon an exposed edge of a glass core in a singulated package substrate unit according to any of the frame printing techniques described above. FIG. 10 is a cross-sectional view illustrating singulation of package substrate panel 800 into package substrate units 1001 comprising core glass 201, in accordance with some embodiments. In the illustrated example, frame material is around a perimeter of package substrate panel 800 such that singulation along kerf lines 720 exposes new edges of core glass 201.

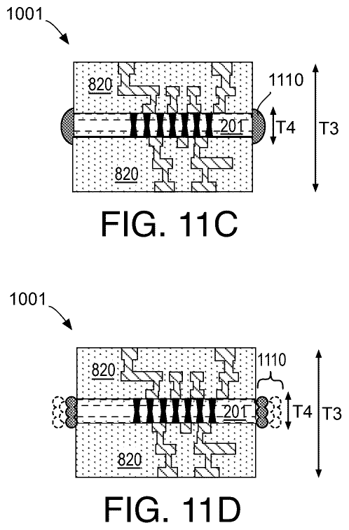

FIG. 11A-11D are cross-sectional views illustrating a singulated package substrate unit 1001 comprising core glass 201 after printing a frame material 1110 in direct contact with a glass edge exposed by package substrate singulation, in accordance with some exemplary embodiments. In FIG. 11A, at least a portion of the edge of core glass 201 within package substrate unit 1001 is protected by frame material 310 that was printed at some point prior to singulation. In contrast, frame material 1110 has been printed subsequent to singulation on another portion of the edge of core glass 201 that was exposed by singulation.

Frame material 1110 may be printed according to any of the techniques described for frame material 310. Frame material 1110 similarly comprises frame material layers 310A-310N, which may have any of the compositions and/or other attributes described elsewhere herein. In the illustrated example, frame material layers 310A-310N have a cumulative layer height substantially equal to package substrate thickness T₃. In some embodiments, frame material 1110 is only printed on sides of package substrate unit 1001 that have an unprotected glass edge. In other embodiments, as illustrated by dashed line in FIG. 11A, frame material 1110 encircles package substrate unit 1001 and may contact frame material 310 that may be present on one or more sides of core glass 201.

FIG. 11B illustrates an example of a singulated package substrate unit 1001 where frame material 1110 encircling core glass 201 is the only frame material present within package substrate unit 1001. A complete absence of frame material 310 may be the result of substrate singulation or may indicate no frame material was printed prior to package substrate singulation. Regardless, frame material 1110 may then be printed after singulation to provide protection of core glass 201 during subsequent assembly and/or customer use.

FIG. 11C illustrates another example of post-singulation frame printing where frame material 1110 is a single bead of frame material of some thickness T₄ less than package thickness T₃ and with convex surface curvature. FIG. 11D illustrates a further example of post-substrate singulation frame printing where frame material 1110 comprises multiple frame material layers printed over an edge surface of core glass 201.

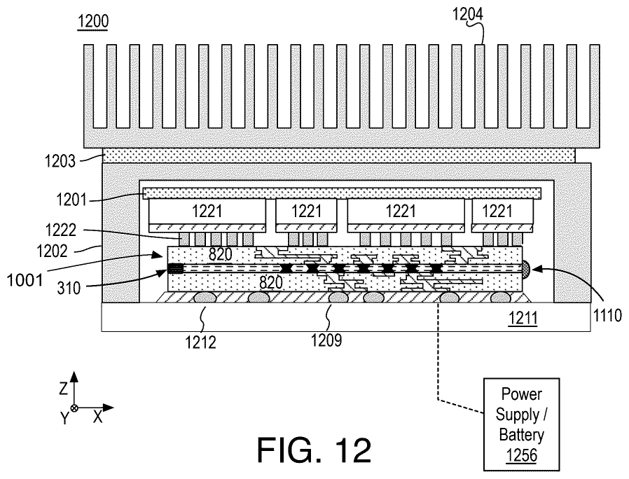

FIG. 12 is a cross-sectional view illustrating a microelectronic device assembly 1200 comprising an IC die package unit 1001 including a core glass 201 protected by one or more frame prints, in accordance with some embodiments. Microelectronic device assembly 1200 includes a plurality of IC dies 1221 joined to package substrate unit 1001 with die-level interconnects 1222. However, any single IC die, 3D stacked multichip device, multi-chip composite structure, or the like may be similarly assembled or directly bonded to glass cored package substrate unit 1001.

A thermal interface material (TIM) 1201 is between IC dies 1221 and a heat spreader and/or lid 1202, which extends beyond a perimeter of package unit 1001, and is mounted to board 1211. Another TIM 1203 is between heat spreader 1202 and a thermal dissipation device 1204, which may be a heat sink, heat pipe or other thermal solution.

Buildup on a second side of package substrate unit 1001 is electrically coupled to a board 1211 with package-level interconnects 1209 (e.g., solder features) that may be at least partially surrounded by underfill material 1212. Board 1211 may include any suitable substrate such as a motherboard, interposer, or the like. Microelectronic device assembly 1300 is coupled to a power supply 1256, for example through one or more of board 1211 and glass cored package substrate unit 1001. Power supply 1256 may include a battery and multi-rail power supply circuitry, such as a switching supply with a voltage converter, etc.

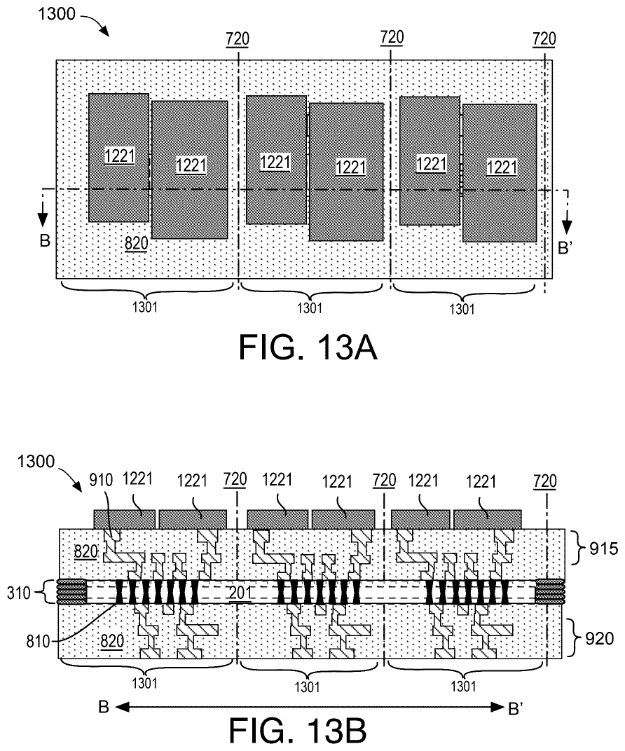

A glass cored package substrate may also be singulated into units after its assembly with one or more IC die. FIGS. 13A and 13B are plan and cross-sectional views illustrating an IC die assembly panel 1300 and subsequent singulation of the panel, in accordance with some embodiments. In this example, each of IC die 1221 are electrically interconnected through direct (hybrid) bonding to package metallization 910, which is further electrically coupled to conductive TGVs 810. Package panel 1300 may be singulated along kerf lines 720 to form discrete glass-cored IC device packages 1301.

Depending on the structure of the package panel 1300 (e.g., the lateral dimensions of core glass 201) any number of glass-cored IC device packages 1301 may be formed from panel 1300. In the illustrated example, following singulation some IC device packages 1301 retain frame material 310 in contact with some portion of the edge of core glass 201 while another portion of the edge may be exposed by singulation. Other IC device packages 1301 may be singulated such that no frame material 310 is retained within the package.

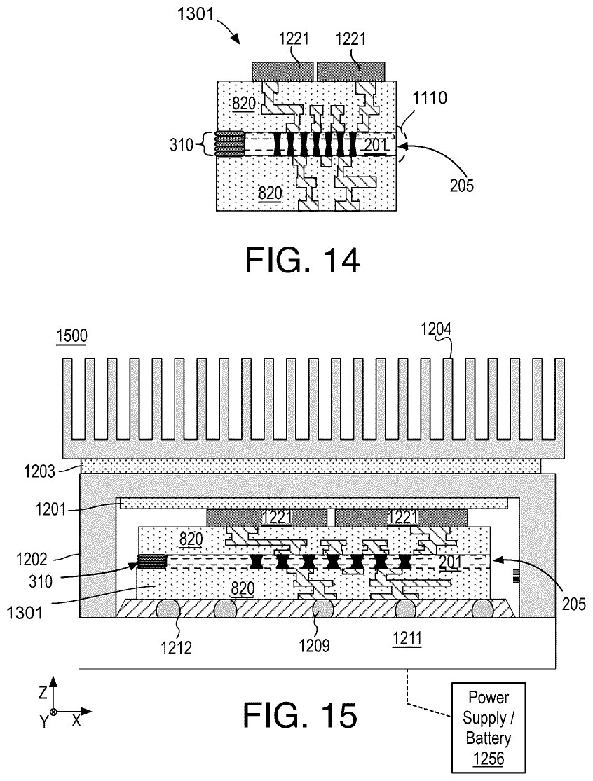

FIG. 14 is a cross-sectional view illustrating a singulated IC device package 1301 comprising a glass core where at least some portion of the edge of the core glass is protected by 3D printed frame material, in accordance with some embodiments. In some examples, IC device package 1301 has only frame material 310 in contact with some edge portion of core glass 201 while frame material 310 is absent from another portion of edge 205. In other examples where frame material is printed subsequent to singulation, a frame material 1110 is in contact with some edge portion of core glass 201 while frame material 310 may optionally be in contact with some other edge portion of core glass 201.

FIG. 15 is a cross-sectional view illustrating a microelectronic device assembly 1500 comprising IC device package 1301 including a core glass 201 protected by one or more frame prints, in accordance with some embodiments. A thermal interface material (TIM) 1201 is between IC dies 1221 and a heat spreader and/or lid 1202, which extends beyond a perimeter of package substrate 1001, and is mounted to board 1211. Another TIM 1203 is between heat spreader 1202 and a thermal dissipation device 1204, which may be a heat sink, heat pipe or other thermal solution. Build up on a second side of IC device package 1301 is electrically coupled to a board 1211 with package-level interconnects 1209 (e.g., solder features) that may be at least partially surrounded by underfill material 1212. Board 1211 may include any suitable substrate such as a motherboard, interposer, or the like. Microelectronic device assembly 1500 is coupled to a power supply 1256, for example through one or more of board 1211 and glass cored IC device package 1301. Power supply 1256 may include a battery and multi-rail power supply circuitry, such as a switching supply with a voltage converter, etc.

Glass-cored package substrate unit 1001 and glass-cored IC device package 1301 may each comprise one or more of the structural features described elsewhere herein. The exemplary frame prints, and methods of printing, described herein may be integrated into a wide variety of computing systems that include such package substrates and/or IC device packages.

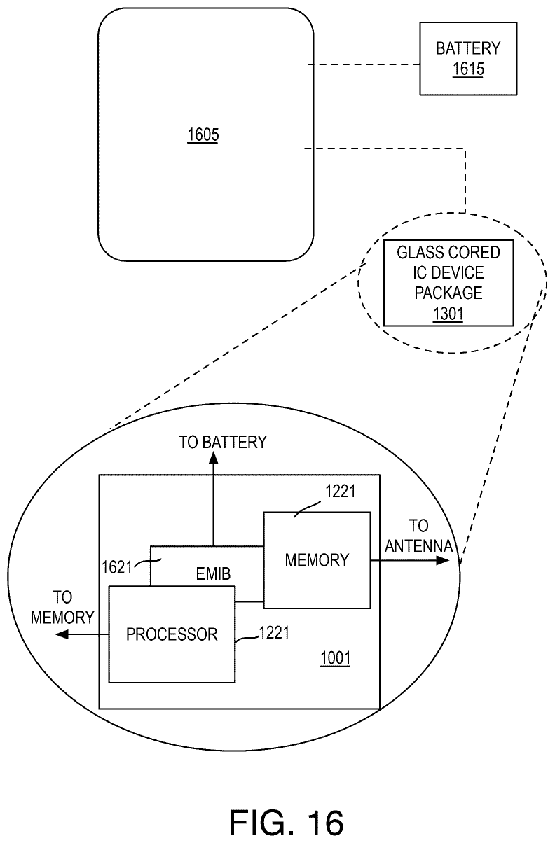

FIG. 16 illustrates a system in which a mobile computing platform or a data server platform 1605 includes a glass-cored IC device package 1301 comprising frame pint in contact with an edge of the core glass, for example as described elsewhere herein. The platform 1605 may be any commercial server, for example including any number of high-performance computing systems within a rack and networked together for electronic data processing. Platform 1605 may alternatively be any portable device configured for each of electronic data display, electronic data processing, wireless electronic data transmission, or the like. For example, platform 1605 may be any of a tablet, a smart phone, laptop computer, etc., and may include a display screen (e.g., a capacitive, inductive, resistive, or optical touchscreen) and a battery 1615.

IC device package 1301 may include memory circuitry (e.g., RAM), and/or a logic circuitry (e.g., a microprocessor, a multi-core microprocessor, graphics processor, or the like) coupled to a glass cored package substrate including one or more edge in contact with a frame print, for example as described elsewhere herein. In the illustrated embodiments, glass-cored package 1301 comprising glass-cored package substrate 1001 hosting a first IC die 1221 comprising processor logic circuitry and hosting a second IC die 1221 comprising memory circuitry. Glass-cored package 1301 further comprises interconnections between IC die 1221, which in this example is in the form of another IC die 1621 embedded within glass-cored package substrate 1001.

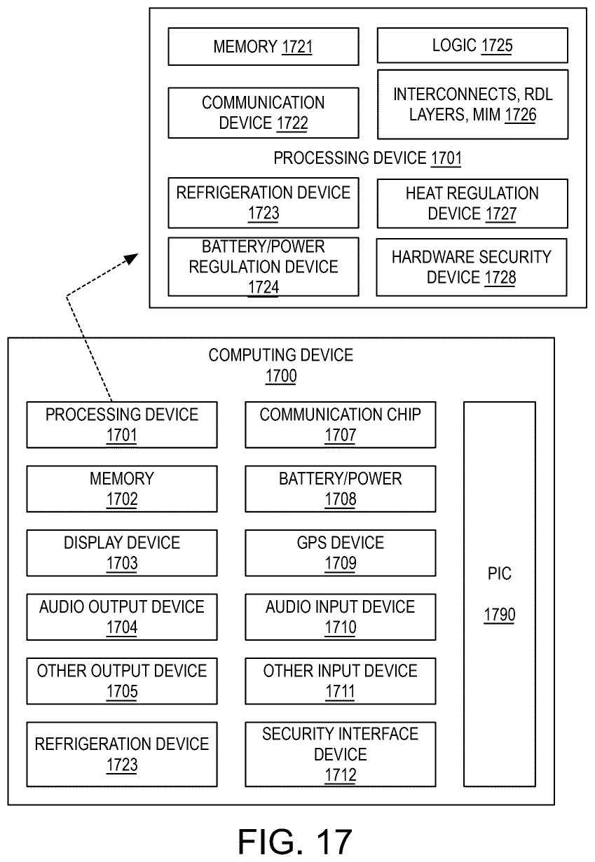

FIG. 17 is a block diagram of a computing device 1700 in accordance with some embodiments. For example, one or more components of computing device 1700 may include any of the glass-cored substrate and/or package structures discussed elsewhere herein. A number of components are illustrated in FIG. 17, but any one or more of these components may be omitted or duplicated, as suitable for the application. In some embodiments, some of the components included in computing device 1700 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Additionally, in various embodiments, computing device 1700 may not include one or more of the components illustrated in FIG. 17, but computing device 1700 may include interface circuitry for coupling to the one or more components. For example, computing device 1700 may not include a display device 1703, but may include display device interface circuitry (e.g., a connector and driver circuitry) to which display device 1703 may be coupled.

Computing device 1700 may include a processing device 1701 (e.g., one or more processing devices). As used herein, the term processing device or processor indicates a device that processes electronic data from registers and/or memory to transform that electronic data into other electronic data that may be stored in registers and/or memory. Processing device 1701 may include a memory 1702, a communication device 1722, a refrigeration/active cooling device 1723, a battery/power regulation device 1724, logic 1725, interconnects 1726, a heat regulation device 1727, and a hardware security device 1728.

Processing device 1701 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable compute units.

Processing device 1701 may include a memory 1721, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 1701 shares a package with memory 1702. This memory may be used as cache memory and may include embedded dynamic random-access memory (eDRAM) or spin transfer torque magnetic random-access memory (STT-M RAM).

Computing device 1700 may include a heat regulation/refrigeration device 1723. Heat regulation/refrigeration device 1723 may maintain processing device 1701 (and/or other components of computing device 1700) at a predetermined low temperature during operation. This predetermined low temperature may be any temperature discussed elsewhere herein.

In some embodiments, computing device 1700 may include a communication chip 1707 (e.g., one or more communication chips). For example, the communication chip 1707 may be configured for managing wireless communications for the transfer of data to and from computing device 1700. The term “wireless” and its derivatives may be used to describe circuits, devices, systems, methods, techniques, communications channels, etc., that may communicate data through the use of modulated electromagnetic radiation through a nonsolid medium.

Computing device 1700 includes a PIC 1790, for example having a photonic integrated WDM source circuit. PIC 1790 may facilitate communication between one or more instances of processing device 1701 and/or one or more instances of memory 1702, for example.

Computing device 1700 may include battery/power circuitry 1708. Battery/power circuitry 1708 may include one or more energy storage devices (e.g., batteries or capacitors) and/or circuitry for coupling components of computing device 1700 to an energy source separate from computing device 1700 (e.g., AC line power).

Computing device 1700 may include a display device 1703 (or corresponding interface circuitry, as discussed above). Display device 1703 may include any visual indicators, such as a heads-up display, a computer monitor, a projector, a touchscreen display, a liquid crystal display (LCD), a light-emitting diode display, or a flat panel display, for example.

Computing device 1700 may include an audio output device 1704 (or corresponding interface circuitry, as discussed above). Audio output device 1704 may include any device that generates an audible indicator, such as speakers, headsets, or earbuds, for example.

Computing device 1700 may include an audio input device 1710 (or corresponding interface circuitry, as discussed above). Audio input device 1710 may include any device that generates a signal representative of a sound, such as microphones, microphone arrays, or digital instruments (e.g., instruments having a musical instrument digital interface (MIDI) output).

Computing device 1700 may include a global positioning system (GPS) device 1709 (or corresponding interface circuitry, as discussed above). GPS device 1709 may be in communication with a satellite-based system and may receive a location of computing device 1700.

Computing device 1700 may include another output device 1705 (or corresponding interface circuitry, as discussed above). Examples include an audio codec, a video codec, a printer, a wired or wireless transmitter for providing information to other devices, or an additional storage device.

Computing device 1700 may include another input device 1711 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1700 may include a security interface device 1712. Security interface device 1712 may include any device that provides security measures for computing device 1700 such as intrusion detection, biometric validation, security encode or decode, managing access lists, malware detection, or spyware detection.

Computing device 1700, or a subset of its components, may have any appropriate form factor, such as a server or other networked computing component, a mobile device, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that embodiments described herein may be practiced with modification and alteration without departing from the scope of the appended claims. For example, the above embodiments may include specific combinations of features as further provided below.

In first examples, an apparatus comprises an integrated circuit (IC) die package substrate. The substrate comprises a glass core having an edge of a thickness between a first side and a second side of the glass core, via metallization features extending through the thickness of the glass core. The apparatus comprises an organic dielectric material over at least one of the first or second sides of the glass core, and one or more layers of organic, inorganic, or composite material in direct contact with an edge of the glass core. An exterior surface of each of the one or more layers has convex curvature.

In second examples, for any of the first examples the convex curvature has a radius of curvature that is no greater than the thickness of the glass core.

In third examples, for any of the second examples the exterior surface with the convex curvature is opposite the edge of the glass core.

In fourth examples, for any of the second or third examples the radius of curvature is no greater than one-half the thickness of the glass core.

In fifth examples, for any of the first through fourth examples the one or more layers comprise a plurality of the layers of organic or inorganic material in a vertical stack from the first side of the glass core to the second side of the core, and each of the layers in the stack is adjacent to a portion of the thickness of the edge.

In sixth examples, for any of the fifth examples a portion of each of the layers has an exterior surface with convex curvature opposite the edge of the glass core.

In seventh examples, for any of the first examples the one or more layers comprise a plurality of the layers of organic or inorganic material in a horizontal stack extending outward from the edge of the glass core, and a first of the layers between the edge of the glass core and a second of the layers.

In eighth examples, for any of the first through seventh examples a first of the layers has a first material composition and a second of the layers has a second material composition.

In ninth examples, for any of the eighth examples at least elastic modulus differs between the first material composition and the second material composition.

In tenth examples, for any of the first through ninth examples at least one of the one or more layers of organic or inorganic material comprises an organic polymer or a metallic material.

In eleventh examples, for any of the tenth examples at least one of the layers comprises an organic polymer.

In twelfth examples, for any of the eleventh examples at least one of the layers has a composition of at least ten atomic percent carbon or at least ten atomic percent fluorine.

In thirteenth examples, for any of the tenth through twelfth examples at least one of the one or more layers of organic or inorganic material comprises an epoxy resin.

In fourteenth examples, an integrated circuit (IC) packaging panel comprises a first glass core unit having a first rectangular perimeter edge of a thickness between front and back sides of the IC packaging panel. The panel comprises a second glass core unit having a second rectangular perimeter edge of the thickness front and back sides of the IC packaging panel. A first length of the first perimeter edge is adjacent to a second length of the second perimeter edge, and the panel comprises one or more beads of organic or inorganic material in direct contact with at least a portion of the first rectangular perimeter edge or the second rectangular perimeter edge.

In fifteenth examples, for any of the fourteenth examples an exterior surface of each of the one or more beads has convex curvature.

In sixteenth examples, for any of the fourteenth through fifteenth examples at least one of the beads is between the first length of the first perimeter edge and the second length of the second perimeter edge.

In seventeenth examples, for any of the fourteenth through sixteenth examples the beads comprise a plurality of beads of organic or inorganic material in a vertical stack from the back side of the panel to the front side of the panel with each of the beads in the stack in direct contact with a portion of the thickness of the edge along the portion of the first rectangular perimeter edge or the second rectangular perimeter edge.

In eighteenth examples, for any of the seventeenth examples the vertical stack has a thickness substantially equal to the thickness of the edge, and wherein each of the beads has a thickness of 0.5 μm to 100 μm.

In nineteenth examples, for any of the fourteenth through eighteenth examples at least one of the beads comprises an epoxy resin.

In twentieth examples, for any of the fourteenth through nineteenth examples the one or more beads define a frame encircling the IC packaging panel, and the one or more beads define both a thickness of frame and lateral width of the frame.

In twenty-first examples, for any of the fourteenth through twentieth examples the packaging panel further comprises a dielectric material in direct contact with at least one of the front or back sides of each of the first and second glass core units. The dielectric material spans a space between the first length of the first perimeter edge and the second length of the second perimeter edge.

In twenty-second embodiments, a method comprises receiving a preform of core glass, the core glass having a thickness between a planar top surface and a planar bottom surface. The method comprises printing one or more beads of organic or inorganic material in direct contact with an edge of the core glass, and the method comprises planarizing the organic or inorganic material with the at least one of the top surface or bottom surface of the core glass.

In twenty-third examples, for any of the twenty-second examples the printing comprises dispensing a powder adjacent to the edge of the glass core and laser sintering at least a portion of the powder in contact with the edge of the glass core.

In twenty-fourth examples, for any of the twenty-second examples the printing comprises extruding a melt onto the edge of the glass core and curing or setting the melt.

In twenty-fifth examples, for any of the twenty-second examples the printing comprises dispensing a photopolymer precursor over the glass core and curing a portion of the photopolymer adjacent to the edge of the glass core.

In twenty-sixth examples, for any of the twenty-second examples the printing comprises iteratively printing a plurality of the beads of the organic or inorganic material to form a stack of the beads, a width or a height of the stack defining an outer perimeter of a frame encircling the glass core.

In twenty-seventh examples, for any of the twenty-second examples through twenty-sixth examples the method further comprises reconstituting a plurality of the glass cores into a panel prior to, concurrently with, or subsequent to, printing the one or more beads, and singulating the panel into a plurality of package substrate units subsequent to printing the one or more beads.

In twenty-eighth examples, for any of the twenty-seventh examples the plurality of the glass cores are reconstituted after printing the one or more beads on individual ones of the glass cores to form a frame encircling each of the glass cores.

In twenty-ninth examples, for any of the twenty-second examples through twenty-eighth examples the method further comprises reconstituting a plurality of the glass cores into a panel,, and singulating the panel into a plurality of package substrate units prior to printing the one or more beads.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims.

What is claimed is:

1. An apparatus, comprising
an integrated circuit (IC) die package substrate, comprising:
a glass core having an edge of a thickness between a first side and a second side of the glass core;
via metallization features extending through the thickness of the glass core;
an organic dielectric material over at least one of the first or second sides of the glass core; and
one or more layers of organic, inorganic, or composite material in direct contact with an edge of the glass core, wherein an exterior surface of each of the one or more layers has convex curvature.

2. The apparatus of claim 1, wherein the convex curvature has a radius of curvature that is no greater than the thickness of the glass core.

3. The apparatus of claim 2, wherein the exterior surface with the convex curvature is opposite the edge of the glass core.

4. The apparatus of claim 2, wherein the radius of curvature is no greater than one-half the thickness of the glass core.

5. The apparatus of claim 1, wherein the one or more layers comprise a plurality of the layers of organic or inorganic material in a vertical stack from the first side of the glass core to the second side of the core, and wherein each of the layers in the stack adjacent to a portion of the thickness of the edge.

6. The apparatus of claim 5, wherein a portion of each of the layers has an exterior surface with convex curvature opposite the edge of the glass core.

7. The apparatus of claim 1, wherein the one or more layers comprise a plurality of the layers of organic or inorganic material in a horizontal stack extending outward from the edge of the glass core, and wherein a first of the layers between the edge of the glass core and a second of the layers.

8. The apparatus of claim 1, wherein a first of the layers has a first material composition and a second of the layers has a second material composition.

9. The apparatus of claim 8, wherein at least elastic modulus differs between the first material composition and the second material composition.

10. The apparatus of claim 1, wherein at least one of the one or more layers of organic or inorganic material comprises an organic polymer or a metallic material.

11. The apparatus of claim 10, wherein at least one of the layers comprises an organic polymer.

12. The apparatus of claim 11, wherein at least one of the layers has a composition of at least ten atomic percent carbon or at least ten atomic percent fluorine.

13. The apparatus of claim 10, wherein at least one of the one or more layers of organic or inorganic material comprises an epoxy resin.

14. An integrated circuit (IC) packaging panel, comprising:
a first glass core unit having a first rectangular perimeter edge of a thickness between front and back sides of the IC packaging panel;
a second glass core unit having a second rectangular perimeter edge of the thickness front and back sides of the IC packaging panel, wherein a first length of the first perimeter edge is adjacent to a second length of the second perimeter edge; and
one or more beads of organic or inorganic material in direct contact with at least a portion of the first rectangular perimeter edge or the second rectangular perimeter edge.

15. The IC packaging panel of claim 14, wherein an exterior surface of each of the one or more beads has convex curvature.

16. The IC packaging panel of claim 14, wherein at least one of the beads is between the first length of the first perimeter edge and the second length of the second perimeter edge.

17. The IC packaging panel of claim 14, wherein the beads comprise a plurality of beads of organic or inorganic material in a vertical stack from the back side of the panel to the front side of the panel with each of the beads in the stack in direct contact with a portion of the thickness of the edge along the portion of the first rectangular perimeter edge or the second rectangular perimeter edge.

18. The IC packaging panel of claim 17, wherein the vertical stack has a thickness substantially equal to the thickness of the edge, and wherein each of the beads has a thickness of 0.5 μm to 100 μm.

19. The IC packaging panel of claim 14, wherein at least one of the beads comprises an epoxy resin.

20. The IC packaging panel of claim 14, wherein the one or more beads define a frame encircling the IC packaging panel, and wherein the one or more beads define both a thickness of frame and lateral width of the frame.
